(19) United States
(12) Patent Application Publication
(10) Pub. No.: US 2025/0105593 A1
(43) Pub. Date: Mar. 27, 2025

(54) VERTICAL-CAVITY SURFACE-EMITTING LASER WITH A REGULATED DOMINANT POLARIZATION STATE

(71) Applicant: Lumentum Operations LLC, San Jose, CA (US)

(72) Inventors: Richa DUBEY, Milpitas, CA (US); Yu ZHANG, Middletown, NJ (US)

(21) Appl. No.: 18/545,962

(22) Filed: Dec. 19, 2023

Related U.S. Application Data
(60) Provisional application No. 63/584,377, filed on Sep. 21, 2023.

(51) Int. Cl. H01S 5/183; H01S 5/062; H01S 5/20

(52) U.S. Cl. CPC H01S 5/18355; H01S 5/06246; H01S 5/18377; H01S 5/18386; H01S 5/209

(57) ABSTRACT

A vertical-cavity surface-emitting laser (VCSEL) may include a distributed Bragg reflector (DBR) stack. The DBR stack may include a mirror structure over a cavity region. The DBR stack may include an etch stop layer over the mirror structure. The DBR stack may include a grating layer over the etch stop layer. The grating layer may include a grating structure associated with polarization of output light emitted by the VCSEL.

### CROSS-REFERENCE TO RELATED APPLICATION

This Patent application claims priority to U.S. Provisional Patent Application No. 63/584,377, filed on Sep. 21, 2023, and entitled “VERTICAL-CAVITY SURFACE-EMITTING LASER WITH A REGULATED DOMINANT POLARIZATION STATE.” The disclosure of the prior Application is considered part of and is incorporated by reference into this Patent Application.

### TECHNICAL FIELD

The present disclosure relates generally to a vertical-cavity surface-emitting laser (VCSEL) and to a VCSEL with a regulated dominant polarization state.

### BACKGROUND

A VCSEL is a semiconductor laser, more specifically a diode laser with a monolithic laser resonator, where light is emitted in a direction perpendicular to a chip surface. Typically, the laser resonator consists of two distributed Bragg reflector (DBR) mirror structures parallel to a chip surface, between which is a cavity region (consisting of one or more quantum wells) that generates light. The upper and lower mirror structures of a VCSEL are doped to form a diode junction by, for example, p-doping the upper mirror structure of the VCSEL and n-doping the lower mirror structure of the VCSEL.

### SUMMARY

In some implementations, a VCSEL includes a DBR stack, comprising: a mirror structure over a cavity region; an etch stop layer over the mirror structure; and a grating layer over the etch stop layer, the grating layer including a grating structure associated with polarization of output light emitted by the VCSEL.

In some implementations, a VCSEL includes a DBR stack, comprising: an etch stop layer associated with controlling etching of a grating layer during formation of a grating structure in the grating layer, wherein the grating structure is associated with providing polarization selectivity for the VCSEL, and wherein the control of the etching provided by the etch stop layer increases polarization stability of the VCSEL and improves the performance and uniformity of the performance of the VCSEL; and the grating layer including the grating structure.

In some implementations, a VCSEL includes a DBR stack, comprising: a grating layer; and an etch stop layer to control an etch depth of the grating layer, wherein the control of the etch depth of the grating layer is associated with regulation of a dominant polarization state of light emitted by the VCSEL.

### BRIEF DESCRIPTION OF THE DRAWINGS

FIGS. 1A and 1B are diagrams associated with an example implementation of a VCSEL with a regulated dominant polarization state as described herein.

FIGS. 2A-2B are diagrams illustrating an effect of grating depth on a direction of preferred polarization and slope efficiency.

FIG. 3 is a diagram illustrating an alternative implementation of the VCSEL with a regulated dominant polarization state described herein.

### DETAILED DESCRIPTION

The following detailed description of example implementations refers to the accompanying drawings. The same reference numbers in different drawings may identify the same or similar elements.

A conventional VCSEL has a cylindrical symmetry and has no preferred polarization state. As a result, a conventional VCSEL emits substantially unpolarized light with a combination of modes lasing in different states of polarization. During operation of the conventional VCSEL, the polarization states can switch from one to another, which is not desired in many applications, such as in an optical system requiring polarization sensitive optics, spectroscopy, or optical communication, among other examples.

A grating may be used to control the polarization of light emitted by a VCSEL. Conventionally, a grating is formed in a layer above a top DBR mirror in a stack of layers of the VCSEL. Here, the layer in which the grating is formed is a layer that is grown on the top DBR mirror stack. That is, the layer in which the grating is formed is conventionally not part of or included in the DBR mirror stack. As a result, a size (e.g., a total thickness) of the VCSEL may be increased and, furthermore, complexity with respect to planarizing a surface of the VCSEL is increased. Further, subsequent deposition of layers above the grating may result in the grating being filled-in (e.g., with the same material as that of the grating). In some scenarios, this filling-in of the grating can reduce an effective depth of the grating such that the grating is very small or practically non-existent.

One alternative to including a separate grating layer in a VCSEL is to incorporate the grating in the layer stack of the VCSEL. However, parameters of the grating need to be carefully controlled in order to ensure that the grating performs as intended, which is difficult when incorporating the grating in the layer stack of the VCSEL. For example, grating performance depends on parameters of the grating, such as grating depth, pitch, duty cycle, and position within the VCSEL. Grating depth in particular has a significant impact on grating behavior. The grating depth can influence a sign of polarization for a given grating design. Unintentional grating depth process variations can cause polarization switching among the VCSELs with the same design within a given die or wafer. Therefore, tighter grating depth control can serve to improve regulation of a dominant polarization state of a VCSEL and, as a result, improve performance uniformity.

Some implementations described herein provide a VCSEL with a regulated dominant polarization state. In some implementations, the VCSEL includes a DBR stack, comprising a mirror structure over a cavity region, an etch stop layer over the mirror structure, and a grating layer over the etch stop layer. Here, the grating layer may include a grating structure associated with polarization of output light emitted by the VCSEL. In some implementations, the etch stop layer is incorporated into the DBR stack. In some implementations, the etch stop layer improves control with respect to formation of the grating structure (e.g., by enabling improved grating depth control). As a result, control of a polarization state of a given VCSEL is improved (e.g., so as to reduce or eliminate polarization switching) and, furthermore, uniformity with respect to performance of VCSELs across a die or wafer is increased. Additional details are provided below.

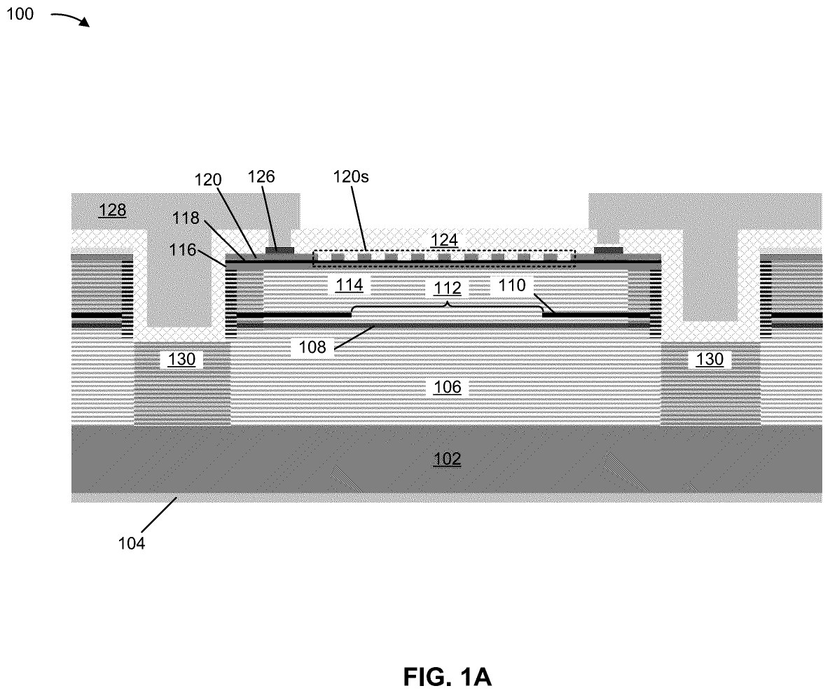

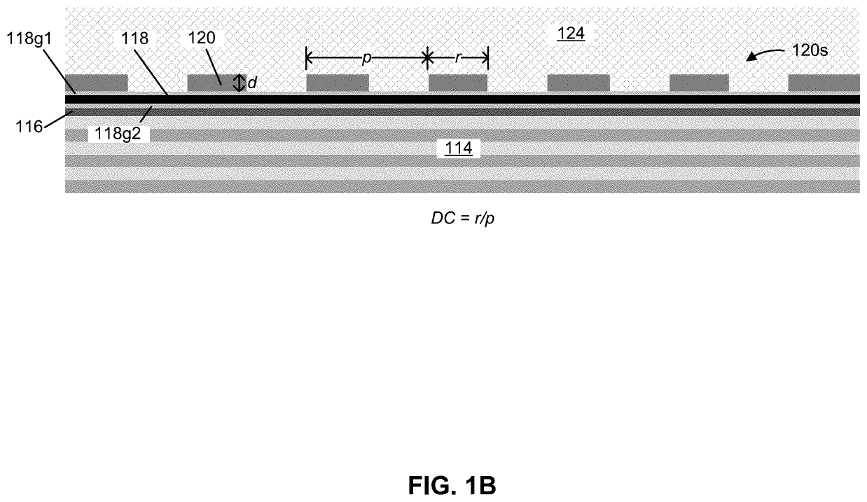

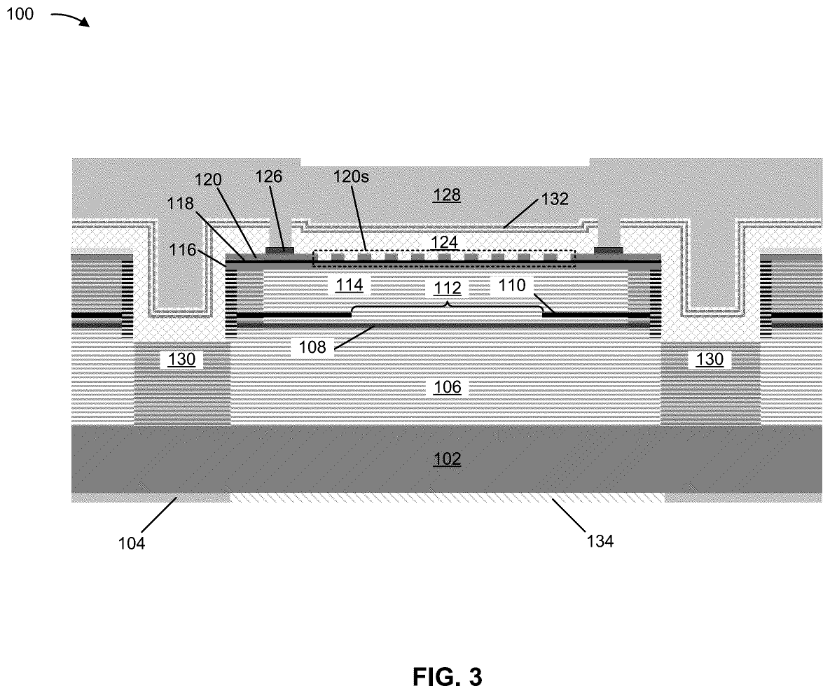

FIGS. 1A and 1B are diagrams associated with an example implementation of a VCSEL 100 with a regulated dominant polarization state as described herein. In some implementations, the VCSEL 100 may be included in an array of emitters (e.g., an array of VCSELs 100). In some implementations, as illustrated in FIG. 1A, the VCSEL 100 is a top-emitting VCSEL, meaning that the VCSEL 100 emits light through a non-substrate side of the VCSEL 100. Alternatively, the VCSEL may in some implementations be a bottom-emitting VCSEL (also referred to as a backside emitting (BSE) VCSEL), meaning that the VCSEL 100 would emit light through the substrate 102 of the VCSEL 100, an example of which is described below with respect to FIG. 3. In some implementations, the VCSEL 100 may be a single mode VCSEL. Alternatively, the VCSEL 100 may be a multi-mode VCSEL.

As shown in FIG. 1A, the VCSEL 100 may include a substrate 102, a bottom metal 104, a bottom mirror structure 106, a cavity including one or more active regions (herein referred to as cavity region(s) 108), a confinement layer 110 that forms a confinement aperture 112, a first top mirror structure 114, a phase matching layer 116, an etch stop layer 118, a grating layer 120, a dielectric layer 124, a contact layer 126, a top metal 128, and one or more isolation implants 130.

Substrate 102 includes a supporting material upon which, or within which, one or more layers or features of the VCSEL 100 are grown or fabricated. In some implementations, the substrate 102 comprises an n-type material. In some implementations, the substrate 102 comprises a semi-insulating type of material. In some implementations, when the VCSEL 100 includes one or more bottom-emitting emitters, the semi-insulating type of material may be used to reduce optical absorption from the substrate 102. In such an implementation, the VCSEL 100 may include a contact buffer in or near the bottom mirror structure 106. In some implementations, the substrate 102 may include a semiconductor material, such as gallium arsenide (GaAs), indium phosphide (InP), or another type of semiconductor material. In some implementations, a bottom contact (e.g., a bottom n-contact) of the VCSEL 100 can be made from a backside of the substrate 102. In some implementations, the bottom contact of the VCSEL 100 can be made from a front side of the VCSEL 100. In some implementations, the front side contact can be achieved by, for example, etching a mesa step or trench to the substrate 102, or inserting a contact buffer in or near the bottom mirror structure 106.

Bottom metal 104 includes a metal layer on a bottom surface of the substrate 102 (e.g., at a backside of the VCSEL 100). In some implementations, the bottom metal 104 is a layer that makes electrical contact with the substrate 102. In some implementations, the bottom metal 104 serves as an anode for the VCSEL 100. In some implementations, the bottom metal 104 may include an annealed metallization layer, such as a gold-germanium-nickel (AuGeNi) layer, or a palladium-germanium-gold (PdGeAu) layer, among other examples.

Bottom mirror structure 106 is a bottom reflector of an optical resonator of the VCSEL 100. For example, the bottom mirror structure 106 may include a plurality of DBR pairs, or another type of mirror structure. In some implementations, the bottom mirror structure 106 is formed from an n-type material. Thus, in some implementations, the bottom mirror structure 106 may include a plurality of n-type DBR pairs. Alternatively, the bottom mirror structure 106 may in some implementations be formed from a p-type material. In some implementations, the bottom mirror structure 106 is on a (top) surface of the substrate 102. In some implementations, the bottom mirror structure 106 may have a thickness in a range from approximately 3.5 micrometers (μm) to approximately 9 μm, such as 5 μm. In some implementations, the bottom mirror structure 106 includes a set of layers (e.g., aluminum gallium arsenide (AlGaAs) layers) grown using a metal-organic chemical vapor deposition (MOCVD) technique, a molecular beam epitaxy (MBE) technique, or another technique.

Cavity region 108 includes one or more layers where electrons and holes recombine to emit light and define the emission wavelength range of the VCSEL 100. For example, the cavity region 108 may include one or more active regions in the form of one or more quantum wells (QWs). In some implementations, the cavity region 108 may include one or more cavity spacer layers (e.g., to enable epitaxial growth to have sufficient room for ramping compositions or temperature). In some implementations, the one or more cavity spacer layers may reduce strain between active regions of the cavity region 108 and/or may mitigate thermal issues of laser operation of the VCSEL 100. In some implementations, the one or more cavity spacer layers may include an oxidation layer. An optical thickness of the cavity region 108 (including the one or more active regions and any cavity spacer layers), the first top mirror structure 114, and the bottom mirror structure 106 may define a resonant cavity wavelength of the VCSEL 100, which may be designed within an emission wavelength range of the cavity region 108 to enable lasing. The wavelength range of the VCSEL 100 may in some implementations be in a range from approximately 940 nanometers (nm) to approximately 1380 nm. In some implementations, the cavity region 108 may be formed on the bottom mirror structure 106. In some implementations, the cavity region 108 includes a set of layers grown using an MOCVD technique, an MBE technique, or another technique.

Confinement layer 110 is a layer that provides optical and/or electrical confinement for the VCSEL 100. In some implementations, the confinement layer 110 enhances carrier and mode confinement of the VCSEL 100 and, therefore, can improve performance of the VCSEL 100. In some implementations, the confinement layer 110 is on, under, or in the cavity region 108. In some implementations, there may be one or more spacer layers or mirror layers (e.g., DBRs) between the confinement layer 110 and the cavity region 108. In some implementations, as shown in FIG. 1A, the confinement layer 110 is on a side of the cavity region 108 nearer to the first top mirror structure 114 (i.e., on a non-substrate side of the cavity region 108). In some implementations, the confinement layer 110 is on a side of the cavity region 108 nearer to the bottom mirror structure 106 (i.e., on a substrate side of the cavity region 108).

In some implementations, the confinement layer 110 comprises an oxide layer formed by oxidation of one or more epitaxial layers of the VCSEL 100. For example, the confinement layer 110 may be an aluminum oxide (Al₂O₃) layer formed as a result of oxidation of an epitaxial layer (e.g., an AlGaAs layer, an AlAs layer, and/or the like). In some implementations, the confinement layer 110 may have a thickness in a range from approximately 0.007 μm to approximately 0.04 μm, such as 0.02 μm. In some implementations, oxidation trenches etched around the VCSEL 100 (shown as filled in FIG. 1A) may allow steam to access the epitaxial layer(s) from which the confinement layer 110 is formed. In some implementations, the oxidation trenches may not fully enclose the confinement layer 110. For example, the oxidation trenches may follow the general shape of the confinement region, but there may be gaps between adjacent oxidation trenches. In some implementations, the confinement layer 110 may follow the general geometric shape, but may have variations associated with shapes or locations of the oxidation trenches and/or variations associated with an oxidation rate. In some implementations, in addition to the confinement layer 110, the VCSEL 100 may include one or more other types of structures or layers that provide current confinement, such as an implant passivation structure, a mesa isolation structure, a moat trench isolation structure, a buried tunnel junction, or the like. Additionally, or alternatively, other types of structures or layers for providing current confinement may be included in or integrated with the confinement layer 110.

In some implementations, the confinement layer 110 defines the confinement aperture 112. Thus, in some implementations, the confinement aperture 112 is an aperture defined by the confinement layer 110. In some implementations, a size (e.g., a width in a given direction) of the confinement aperture 112 is in a range from approximately 1 μm to approximately 300 μm, such as 5 μm or 8 μm. In some implementations, as described above, the confinement aperture 112 may be formed by oxidation (e.g., when the confinement layer 110 is an oxidized layer). Additionally, or alternatively, the confinement aperture 112 may be formed by other means, such as by implantation, diffusion, regrowth (e.g., using a high resistance layer, a current blocking layer, a tunnel junction, or the like), or an air gap, among other examples.

First top mirror structure 114 is a top reflector of the optical resonator of the VCSEL 100. For example, the first top mirror structure 114 may include a plurality of DBR pairs, or another type of mirror structure. In some implementations, the first top mirror structure 114 is formed from a p-type material. Thus, in some implementations, the first top mirror structure 114 comprises a plurality of p-type DBR pairs. Alternatively, the first top mirror structure 114 may in some implementations be formed from an n-type material. In some implementations, the first top mirror structure 114 may have a thickness in a range from approximately 1 μm to approximately 4 μm, such as 2 μm. In some implementations, the first top mirror structure 114 includes a set of layers (e.g., AlGaAs layers) grown using an MOCVD technique, an MBE technique, or another technique. In some implementations, the first top mirror structure 114 is grown on or over the cavity region 108.

Phase matching layer 116 is a layer associated with improving reflectance of the VCSEL 100. For example, the phase matching layer 116 may be a layer configured to cause reflections among layers of the VCSEL 100 to be approximately phase matched at a lasing wavelength of the VCSEL 100 in order to improve reflectance of the VCSEL 100. As shown in FIG. 1A, the phase matching layer 116 may be between the top mirror structure 114 and the etch stop layer 118. In some implementations, the phase matching layer 116 comprises a GaAs layer. In some implementations, a thickness of the phase matching layer 116 may be in a range from approximately 0.10 μm to approximately 0.50 μm, such as 0.25 μm.

Etch stop layer 118 is a layer associated with controlling one or more parameters of the grating structure 120s during etching of the grating layer 120. That is, the etch stop layer 118 is a layer associated with controlling etching of the grating layer 120 during formation of the grating structure 120s in the grating layer 120. In some implementations, as shown in the VCSEL 100, the etch stop layer 118 is incorporated in a DBR stack of the VCSEL 100. That is, the etch stop layer 118 may be incorporated in a layer stack comprising a plurality of epitaxial layers that form the bottom mirror structure 106, the first top mirror structure 114, the phase matching layer 116, and the grating layer 120.

In some implementations, the etch stop layer 118 comprises a material with a high etch selectivity with respect to the grating layer 120. For example, the etch stop layer 118 may comprise a material with an etch selectivity that is greater than 10 (i.e., the grating layer 120 etches 10 times faster than the etch stop layer 118). In some implementations, the etch stop layer 118 may comprise a material that has an etch selectivity of at least 100. In some implementations, a refractive index of the material of the etch stop layer 118 may be within approximately 20% of a refractive index of a material of the grating layer 120. In some implementations, the refractive index of the material of the etch stop layer is greater than approximately 3.0. For example, in some implementations, the material of the etch stop layer 118 has a refractive index in a range from approximately 3.0 to approximately 3.5. In some implementations, the material of the etch stop layer 118 (e.g., along with other layers of the VCSEL 100) is lattice matched with a material of the substrate 102 of the VCSEL 100. In some implementations, the etch stop layer 118 may comprise indium gallium phosphide (InGaP) (e.g., when the substrate 102 comprises GaAs). In some implementations, a thickness of the etch stop layer 118 is in a range from approximately 10 nanometers (nm) to approximately 100 nm, such as 20 nm.

In some implementations, a depth of the grating structure 120s in the DBR stack (e.g., a depth from a top surface of the grating layer 120 to the top of the etch stop layer 118) is associated with providing a dominant state of polarization of the VCSEL 100. Additionally, or alternatively, the etch depth of the grating structure 120s may be associated with reducing or preventing polarization instability of the VCSEL 100. Furthermore, the etch stop layer 118 may control the etch depth of the grating structure 120s so as to provide improved grating depth control and uniformity of performance of the VCSEL 100, such as improved slope efficiency. Additional details regarding the impact of etch depth control provided by the etch stop layer 118 are provided below.

Grating layer 120 is a layer comprising a grating structure 120s. In some implementations, the grating structure 120s may be associated with polarization of output light emitted by the VCSEL 100. In some implementations, the grating layer 120 comprises a GaAs layer. In some implementations, a thickness of the grating layer 120 may be in a range from approximately 0.1 μm to approximately 0.4 μm, such as 0.2 μm.

In some implementations, the grating structure 120s may introduce a polarization dependence to reflectivity of the VCSEL 100, an effect of which is suppression of one of the two orthogonal polarization orientations in the light (e.g., such that the light emitted by the VCSEL 100 has a single polarization orientation). In general, a grating such as the grating structure 120s generates anisotropic reflectivity or, in other words, different reflectivity for the transverse electric (TE) and transverse magnetic (TM) polarizations. The state of polarization with the lower reflectivity becomes comparatively more lossy and requires a higher threshold current. Eventually, the state of the polarization with the lower reflectivity either does not enter a stimulated emission regime at an operating current or lases near threshold with low power. The higher the power difference between the two polarization states, the stronger the polarization selectivity (i.e., the larger the polarization extinction ratio (PER)). Since reflectivity is altered by the presence of a grating, penalties on performance can be expected. In some implementations, the grating structure 120s of the VCSEL 100 can be designed using a rigorous coupled-wave analysis method so as to be optimized to minimize penalties on performance (e.g., threshold current or slope efficiency). In some implementations, the grating structure 120s reduces or eliminates polarization switching in the VCSEL 100 by achieving a single dominating polarization state. Thus, in some implementations, the use of the etch stop layer 118 to control the formation of the grating structure 120s enables the single dominating polarization state to be achieved in the VCSEL 100. In some implementations, the grating structure 120s may be associated with increasing reflectivity on a side of the VCSEL 100 that includes the first top mirror structure 114.

In some implementations, the grating structure 120s can be formed by etching of the grating layer 120. In some implementations, the grating structure 120s has a grating depth d and a pitch (or period) p that are on an order of or lower than a wavelength of the VCSEL 100. In some implementations, the grating structure 120s may have a periodic pattern or an aperiodic pattern. Additionally, or alternatively, the grating structure may have a variety of shapes, such as a rectangular shape, a square shape, a triangular shape, a sinusoidal shape, among other examples, depending on a need in a given application. In some implementations, the grating structure 120s can be formed using photolithography technique, deep ultraviolet (UV) lithography, nano-imprint lithography, or e-beam lithography, among other examples. In some implementations, the grating structure 120s has a sub-wavelength scale feature size. In some implementations, as determined by grating design, the polarization that is provided by the grating structure 120s can be in a direction parallel to grooves of the grating structure 120s or can be in a direction perpendicular to the grooves of the grating structure Notably, the grating structure 120s can be used for any shape of confinement aperture 112, such as a circular confinement aperture 112 or an asymmetric confinement aperture 112. Further, the grating structure 120s can in some implementations fully cover the VCSEL 100. Alternatively, a shape of the grating structure 120s may in some implementations match a shape of the confinement aperture 112. In some implementations, an overlap (within a tolerance) or a slightly larger grating structure 120s than confinement aperture 112 may be used.

FIG. 1B is a diagram illustrating a close-up view of the grating structure 120s illustrated in FIG. 1A. As shown, the grating structure 120s may have a grating depth d, a pitch p, and a ridge width r. As shown, a duty cycle DC of the grating structure 120s may be a value equal to a ratio of the ridge width r to the pitch p. In some implementations, the grating depth d is approximately equal to the thickness of the grating layer 120. In some implementations, the grating depth d of the grating structure 120s is in a range from approximately 100 nm to approximately 400 nm (e.g., for a lasing wavelength in a range from approximately 940 nm to approximately 1380 nm). In some implementations, for a top-emitting VCSEL 100, the pitch p of the grating structure 120s may be in a range from approximately (e.g., +0.02 μm) 0.20 μm to approximately 0.31 μm at lasing wavelength of 940 nm. Additionally, or alternatively, for a top-emitting VCSEL 100, the pitch p of the pattern may be in a range from approximately 0.21×λ to approximately 0.33×λ, where λ is a design wavelength of the top-emitting VCSEL 100. In some implementations, for a bottom-emitting VCSEL 100, the pitch p of the grating structure 120s may be in a range from approximately (e.g., ±0.02 μm) 0.35 μm to approximately 0.45 μm at lasing wavelength of 940 nm. Additionally, or alternatively, for a bottom-emitting VCSEL 100, the pitch p of the pattern may be in a range from approximately 0.37×λ to approximately 0.48×λ, where λ is a design wavelength of the bottom-emitting VCSEL 100. In some implementations, the duty cycle DC of the pattern may be in a range from approximately (e.g., ±0.03) 0.40 to approximately 0.60.

As shown in FIG. 1B, the VCSEL 100 may, in some implementations, include one or more grading layers 118g. A grading layer 118g is a layer that mitigates an impact of a band misalignment between a material of the etch stop layer 118 and a material of a layer adjacent to the etch stop layer 118. In one example, there may be a semiconductor band misalignment between an InGaP etch stop layer 118 and a GaAs layer adjacent to the etch stop layer 118 (e.g., the grating layer 120, the phase matching layer 116, a top layer of the first top mirror structure 114). Here, a grading layer 118g may comprise a material with a band alignment that falls between that of InGaP and GaAs. In some implementations, the grading layer 118g can improve electrical performance of the VCSEL (e.g., if the etch stop layer 118 increases voltage or resistance for VCSEL 100 as a result of band misalignment). In some implementations, a grading layer 118g may comprise a plurality of thin layers, with the plurality of thin layers providing multiple, small steps in terms of band alignment between the material of the etch stop layer 118 and the adjacent material. For example, a grading layer 118g may comprise a plurality of thin layers, with the plurality of thin layers providing multiple, small steps in terms of band alignment between an InGaP etch stop layer 118 and an adjacent GaAs layer.

As shown in FIG. 1B, the VCSEL 100 in some implementations includes an upper grading layer 118g1 (e.g., between the etch stop layer 118 and the grating layer 120). The band alignment of the upper grading layer 118g1 may be between a band alignment of a material of the etch stop layer 118 and a band alignment of a material of the grating layer 120. Additionally, or alternatively, the VCSEL 100 may include a lower grading layer 118g2 (e.g., between the etch stop layer 118 and the layer below the etch stop layer 118). The band alignment of the lower grading layer 118g2 may be between a band alignment of a material of the etch stop layer 118 and a band alignment of a material of a layer that is below the lower grading layer 118g2 (e.g., the top layer of the first top mirror structure 114, or the phase matching layer 116 (if present)). In some implementations, a thickness of the grading layer 118g may be in a range from approximately 0.004 μm to approximately 0.02 μm, such as 0.012 μm. In some implementations, a grading layer 118g (e.g., the upper grading layer 118g1, the lower grading layer 118g2) comprises AlGaAs. Notably, an etch selectivity between GaAs and AlGaAs is small (i.e., etching selectivity between GaAs and AlGaAs is lacking). Thus, InGaP could still be used for the etch stop layer 118 if the upper grading layer 118g1 is included on the top side of the etch stop layer 118. However, for some other designs, if there is not a good grading material in terms of lacking selectivity between the grating layer 120 and the grading layer 118g, but there exists good etch selectivity between the material of the grading layer 118g and the material of the etch stop layer 118, then the VCSEL 100 may include only the lower grading layer 118g2 (e.g., rather than both the upper grading layer 118g1 and the lower grading layer 118g2).

Returning to FIG. 1A, dielectric layer 124 is a layer that at least partially insulates the top metal 128 from one or more other layers or features (e.g., sidewalls of trenches). Further, the dielectric layer 124 may serve to protect the grating layer 120. In some implementations, the dielectric layer 124 may comprise, for example, silicon nitride (SiN_{X}), silicon dioxide (SiO₂), a polymer dielectric, or another type of insulating material. In some implementations, the dielectric layer 124 has a thickness that is approximately equal to a multiple of (λ/2)×n, where λ is a design wavelength of the VCSEL 100 and n is a refractive index of a material of the dielectric layer 124.

Top contact layer 126 is a top contact layer of the VCSEL 100 that makes electrical contact with the first top mirror structure 114 through which current may flow. In some implementations, the top contact layer 126 is formed from materials optimized for contacting a p-type semiconductor. Alternatively, the contact layer 126 is in some implementations formed from materials optimized for contacting an n-type semiconductor. In some implementations, the top contact layer 126 has a thickness in a range from approximately 0.2 μm to approximately 0.3 μm, such as 0.25 μm. In some implementations, the top contact layer 126 has a ring shape, a slotted ring shape, a tooth wheel shape, or another type of circular or non-circular shape (e.g., depending on a design of the VCSEL 100).

In some implementations, as shown in FIG. 1A, the top contact layer 126 is over the grating layer 120 (e.g., on the grating layer 120). Alternatively, the top contact layer 126 may in some implementations be in an opening in the grating layer 120.

The top metal 128 is a top metal layer at a front side of the VCSEL 100. In some implementations, the top metal 128 may be a layer that makes electrical contact with the top contact layer 126 (e.g., through vias in the dielectric layer 124 and the second top mirror structure 132 in the case of a bottom-emitting VCSEL 100 as illustrated in the example shown in FIG. 3). In some implementations, the top metal 128 may serve as a cathode for the VCSEL 100. In some implementations, the top metal 128 may comprise a plating metal (e.g., a gold (Au)) and/or a seed metal (e.g., TiW/Au).

Isolation implant 130 is a region to prevent free carriers from reaching edges of trenches and/or to isolate adjacent VCSELs 100 from one another (e.g., if the trenches do not fully enclose the VCSELs of the VCSEL 100). Isolation implant 130 may comprise, for example, an ion implanted material, such as a hydrogen/proton implanted material or a similar implanted element to reduce conductivity.

The number, arrangement, thicknesses, order, symmetry, or the like, of layers shown in FIGS. 1A and 1B are provided as examples. In practice, the VCSEL 100 may include additional layers, fewer layers, different layers, differently constructed layers, or differently arranged layers than those shown in FIGS. 1A and 1B. Additionally, or alternatively, a set of layers (e.g., one or more layers) of the VCSEL 100 may perform one or more functions described as being performed by another set of layers of the VCSEL 100, and any layer may comprise more than one layer.

As noted above, grating performance depends on a number of factors, such as grating depth, pitch, duty cycle, and position, with the grating depth having a comparatively stronger effect on grating behavior. As described above, the grating depth can influence the polarization of a VCSEL for a given grating design, and unintentional grating depth process variations can cause polarization switching among conventional VCSELs with the same design within a die or wafer.

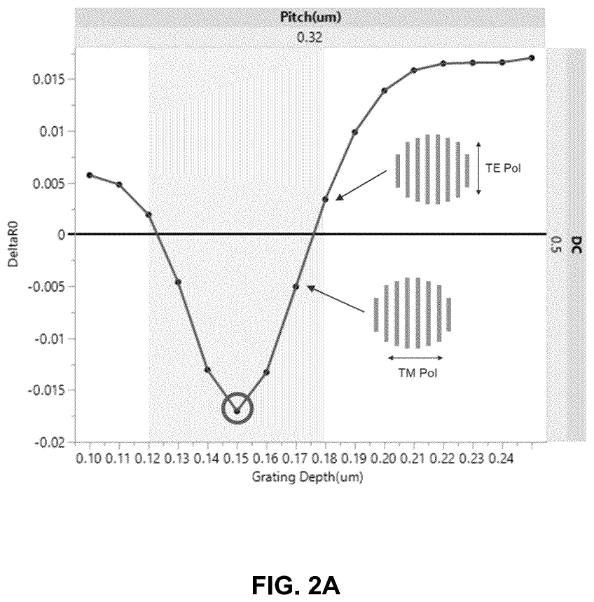

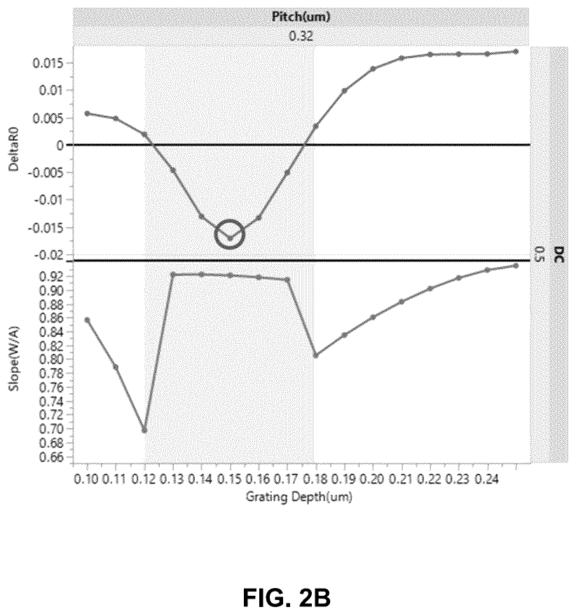

FIG. 2A is a diagram illustrating an effect of grating depth on a direction of preferred polarization for a specific grating design with a pitch p of 0.32 μm, a duty cycle DC of 0.5, and for a VCSEL with a wavelength of 940 nm. In FIG. 2A, DeltaR0 is a difference of reflectivity of a 0^{th} order of the TE polarization state and the TM polarization state. The sign of DeltaR0 can be directly related to the direction of dominant polarization state: a positive DeltaR0 represents the dominant polarization state being parallel to the direction grating grooves, while a negative DeltaR0 represents the dominant polarization state being perpendicular to the grating grooves. As highlighted by the shaded region in FIG. 2A, the sign of DeltaR0 switches at grating depths of approximately 125 nm and 175 nm. Here, an unintended process variation around a target grating depth of approximately 150 nm (indicated by the circle in FIG. 2A) would cause the dominant polarization state to switch from TM to TE, even though the intended polarization for this particular grating design is perpendicular to the grating grooves.

To avoid the polarization switching that could otherwise result from process variations, the VCSEL 100 includes the etch stop layer 118 described herein. The etch stop layer 118 provides tighter grating depth process control, meaning that the etch stop layer 118 enables stabilization of the dominant polarization state and, therefore, improves performance uniformity among VCSELs 100 (e.g., as compared to conventional VCSELs that do not include the etch stop layer 118).

FIG. 2B adds a constraint on VCSEL efficiency-only particular grating thicknesses will allow sufficient gain for a VCSEL. Slope efficiency is depicted in FIG. 2B to illustrate an impact of grating depth on VCSEL performance. As can be seen in FIG. 2B, at the dip of DeltaR0 (negative maximum), there is a comparatively higher and flatter region in slope efficiency, which makes these design points preferable (e.g., due to less penalty of performance). Notably, the desired slope efficiency region is relatively close to the regions where the polarization switches at ±25 nm from the target grating depth of 150 nm, and the slope efficiency drops significantly around this region (e.g., up to approximately 24%). For a time-based etching technique in a conventional VCSEL (without the etch stop layer 118), the etch depth control could be target etch depth plus or minus approximately 15%. Therefore, without the use of the etch stop layer 118, unintended process variations could cause the slope efficiency of the VCSEL to fall outside of the range of preferable design points, meaning that VCSEL performance would be degraded.

Therefore, to avoid the negative impact on performance that could otherwise result from process variations, the VCSEL 100 includes the etch stop layer 118 described herein. The etch stop layer 118 provides tighter grating depth process control, meaning that the etch stop layer 118 improves performance of the VCSEL 100, and uniformity of the performance of the VCSEL 100 (e.g., as compared to a conventional VCSEL that does not include the etch stop layer 118).

As indicated above, FIGS. 2A-2B are provided as examples. Other examples may differ from what is described with regard to FIGS. 2A-2B.

FIG. 3 is a diagram illustrating an alternative implementation of the VCSEL 100. In the alternative implementation shown in FIG. 3, the VCSEL 100 is a bottom-emitting emitter (rather than a top-emitting emitter as shown in FIG. 1A). In a bottom-emitting configuration, as shown in FIG. 3, the VCSEL 100 may further include a second top mirror structure 132 over the first top mirror structure 114. That is, the VCSEL 100 may in some implementations include a second DBR stack over the first DBR stack (e.g., a DBR stack over that in which the etch stop layer 118 is formed). In some implementations, the first top mirror structure 114 and the second top mirror structure 132 may, in combination with the grating structure 120s, serve to provide a total feedback to a cavity of the VCSEL 100 and control of the polarization of the VCSEL 100.

Second top mirror structure 132 is a top reflector of the optical resonator of the VCSEL 100. In some implementations, the second top mirror structure 132 is configured to increase reflectivity on the side of the VCSEL 100 that includes the first top mirror structure 114 (e.g., the top side of the VCSEL 100). In operation, integration of an optical element, such as a grating structure 120s described herein, in a bottom-emitting VCSEL is less effective (e.g., as compared to a top emitting VCSEL) because of high reflectivity and less interaction of cavity modes with the optical element. Reducing a quantity of mirror pairs in a top mirror structure would increase coupling of the cavity modes with such an optical element. However, reducing the quantity of mirror pairs in the top mirror structure reduces reflectivity in the side of the VCSEL comprising the top mirror structure. In VCSEL 100, the second top mirror structure 132 serves to increase reflectivity in the side of the VCSEL 100 including the first top mirror structure 114. Therefore, the quantity of mirror pairs in the first top mirror structure 114 can be reduced, and the second top mirror structure 132 can be designed to mitigate the reduction in reflectivity caused by the decrease in the quantity of mirror pairs in the first top mirror structure 114. In some implementations, the second top mirror structure 132 may include a plurality of DBR pairs, or another type of mirror structure. In some implementations, the second top mirror structure 132 is formed from a dielectric material. Thus, in some implementations, the second top mirror structure 132 comprises a plurality of dielectric DBR pairs. For example, the second top mirror structure 132 may comprise a plurality of SiO₂/SiNx mirror pairs, a plurality of SiO₂/titanium dioxide (TiO₂) mirror pairs, or a plurality of Al₂O₃/TiO₂ mirror pairs, among other examples. In some implementations, the second top mirror structure 132 is formed from a semiconductor material. Thus, in some implementations, the second top mirror structure 132 comprises a plurality of semiconductor DBR pairs. In some implementations, the second top mirror structure 132 may have a thickness in a range from approximately 2 μm to approximately 4 μm, such as 2.5 μm.

As further shown in FIG. 3, the VCSEL 100 may in some implementations include an anti-reflective (AR) coating 134 in an opening in the bottom metal 104 (e.g., an opening through which the bottom-emitting VCSEL 100 is to emit light).

As indicated above, FIG. 3 provided as an example. Other examples may differ from what is described with regard to FIG. 3.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL), comprising:
a distributed Bragg reflector (DBR) stack, comprising:
a mirror structure over a cavity region;
an etch stop layer over the mirror structure; and
a grating layer over the etch stop layer, the grating layer including a grating structure associated with polarization of output light emitted by the VCSEL.

2. The VCSEL of claim 1, further comprising a phase matching layer between the mirror structure and the etch stop layer.

3. The VCSEL of claim 1, wherein a thickness of the etch stop layer is in a range from approximately 10 nanometers (nm) to approximately 100 nm.

4. The VCSEL of claim 1, wherein a material of the etch stop layer is lattice matched with a material of a substrate of the VCSEL.

5. The VCSEL of claim 1, wherein a material of the etch stop layer has high etch selectivity.

6. The VCSEL of claim 1, wherein a refractive index of a material of the etch stop layer is within approximately 20% of a refractive index of a material of the grating layer.

7. The VCSEL of claim 1, wherein a refractive index of a material of the etch stop layer is greater than or equal to 3.0.

8. The VCSEL of claim 1, wherein the etch stop layer comprises indium gallium phosphide (InGaP).

9. The VCSEL of claim 1, wherein a pitch of the grating structure is in a range from approximately 0.20 micrometers (μm) to approximately 0.45 μm at lasing wavelength of 940 nanometers.

10. The VCSEL of claim 1, wherein a pitch of the grating structure is in a range from approximately 0.21×λ to approximately 0.48×λ, where λ is a wavelength of the VCSEL.

11. The VCSEL of claim 1, wherein a duty cycle of the grating structure is in a range from approximately 0.40 to approximately 0.60.

12. The VCSEL of claim 1, wherein a depth of the grating structure is in a range from approximately 100 nanometers (nm) to approximately 400 nm.

13. The VCSEL of claim 1, wherein an etch depth of structure is associated with reducing or preventing polarization instability of the VCSEL.

14. The VCSEL of claim 1, wherein an etch depth of the grating structure is associated with improving performance of the VCSEL.

15. The VCSEL of claim 1, further comprising at least one of an upper grading layer between the etch stop layer and the grating layer, or a lower grading layer between the etch stop layer and a layer below the etch stop layer.

16. The VCSEL of claim 15, wherein a material of the upper grading layer or the lower grading layer has a band alignment that is between a band alignment of a material of the etch stop layer and a band alignment of a material of the grating layer or the layer below the etch stop layer.

17. The VCSEL of claim 15, wherein the at least one of the upper grading layer or the lower grading layer comprises aluminum gallium arsenide (AlGaAs).

18. The VCSEL of claim 1, wherein the DBR stack is a first DBR stack, and the VCSEL further comprises a second DBR stack over the first DBR stack.

19. A vertical-cavity surface-emitting laser (VCSEL), comprising:
a distributed Bragg reflector (DBR) stack, comprising:
an etch stop layer associated with controlling etching of a grating layer during formation of a grating structure in the grating layer,
wherein the grating structure is associated with providing polarization selectivity for the VCSEL, and
wherein the control of the etching provided by the etch stop layer increases polarization stability of the VCSEL and improves performance and uniformity of the performance of the VCSEL; and
the grating layer including the grating structure.

20. A vertical-cavity surface-emitting laser (VCSEL), comprising:
a distributed Bragg reflector (DBR) stack, comprising:
a grating layer; and
an etch stop layer to control an etch depth of the grating layer, wherein the control of the etch depth of the grating layer is associated with regulation of a dominant polarization state of light emitted by the VCSEL.
